(19) United States
(12) Patent Application Publication
(10) Pub. No.: US 2005/0275310 A1
(43) Pub. Date: Dec. 15, 2005

(54) Method for eletronic operation of a control device for an ultrasound piezoelectric actuator

(75) Inventor: Christophe Ripoll, Viroflay (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: RENAULT S.A.S., Boulogne Billancourt (FR)

(21) Appl. No.: 10/518,435

(22) PCT Filed: Jun. 17, 2003
(86) PCT No.: PCT/FR03/01825

§ 371 Date: Jul. 1, 2005

(30) Foreign Application Priority Data
Jun. 21, 2002 (FR) 02/07705

(51) Int. Cl. H01L 41/09

(52) U.S. Cl. 310/317

(57) ABSTRACT

The invention relates to a method for operation of a control device for at least one ultrasound piezoelectric actuator, comprising an a.c. converter with an assembly having a transformer connected to a voltage source by means of at least one controlled switch and providing an alternating driving voltage for the actuator such that: the voltage (Vc) at the connections for the load comprising the transformer, a resonant inductance and the actuator, is a square wave with the fixed chopping frequency (fr), the current (Ic) flowing in the load is a periodic signal with resonant frequency (fo), such that the operational mode of the switches is of the type hypo-discontinuous, hyper-continuous or hypo-continuous. Said modes are obtained from the relationship of the transformation of the transformer and the inductance of the resonance determined as a function of the equivalent capacitance of the actuator. The above finds application to the injection of fuel in a thermal engine on a motor vehicle.

The present invention relates to a method for electronic activation of the driver device of an ultrasonic piezoelectric actuator, and more particularly to a fuel injector having a piezoelectric stage activated by the electronic injection computer of an internal combustion engine in a motor vehicle.

More precisely, the problem that the invention is intended to solve is the activation of an electronic driver device that causes excitation of piezoelectric cells in order to make the structure of an injector vibrate, such a device being described in French Patent Application filed under No. 01-14023 in the name of the Applicant. A fuel injector containing an ultrasonic piezoelectric stage is intended to atomize the fuel very finely, with droplets whose size is gauged to ensure precise dosage and is sufficiently small that complete and homogeneous vaporization of the injected fuel is ensured. Such an injector is composed of, among other components, a cylindrical nozzle fed with fuel and provided at its end with an injection orifice, and of means, such as a transducer, for causing the nozzle to vibrate cyclically, comprising a piezoelectric ceramic stage, at the terminals of which the electric voltage is varied to modify its thickness between two extreme positions corresponding to opening and closing of the injector within a given reduction ratio. A piezoelectric ceramic stage of an injector is equivalent within a first approximation to a capacitor of high charging voltage, greater than about one hundred volts. This transducer is activated in duration and intensity by an electronic driver device, which itself is activated by the electronic control system of the engine to cause oscillating opening of the nozzle nose at ultrasonic frequency.

The electronic driver device is intended to generate a high-voltage AC signal, greater than about one hundred volts, at a high frequency, above about ten kilohertz, in order to excite the piezoelectric cells from a DC voltage source. In a motor vehicle, the battery delivers a supply voltage of 12 or 42 volts, which requires that this voltage must be boosted by a DC-to-DC step-up voltage converter supplied by the low voltage of the battery.

The purpose of the present invention is to activate electronically the driver switches of the driver device of the injectors, which switches are different from the injector-selection switches, and to do so relative to the load composed of a transformer, a resonance inductor and an injector.

The object of the invention is therefore a method for electronic activation of the driver device of at least one ultrasonic piezoelectric actuator from a control computer that is provided with a DC-to-AC step-up voltage converter supplied by a DC voltage source, the high-voltage output of which is connected to an oscillating circuit composed of the actuator and a resonance inductor, the said converter being composed of a circuit having at least one transformer with at least one primary winding connected to the voltage source by at least one drivable switch and a single secondary winding delivering an AC signal for excitation of the piezoelectric actuator, characterized in that:
the voltage V_{c} at the terminals of the load composed of the transformer, resonance inductor and actuator is a square-wave signal of specified chopping frequency fr, and
the current I_{c} flowing in the load is a periodic signal of resonance frequency fₒ such that twice its value is greater than the chopping frequency fᵣ, fr<2 f₀, in such a way that, upon closing of the switches, the current is zero in the circuit, this hypo-discontinuous type of mode of activation of the switches being obtained from the transformation ratio of the transformer and of the resonance inductor determined as a function of the equivalent capacitance of the actuator.

According to another characteristic, the method for electronic activation of the driver device of at least one ultrasonic piezoelectric actuator from a control computer that is provided with a DC-to-AC step-up voltage converter supplied by a DC voltage source, the high-voltage output of which is connected to an oscillating circuit composed of the actuator and a resonance inductor, the said converter being composed of a circuit having at least one transformer with at least one primary winding connected to the voltage source by at least one drivable switch and a single secondary winding delivering an AC signal for excitation of the piezoelectric actuator, is characterized in that:
the voltage V_{c} at the terminals of the load composed of the transformer, resonance inductor and actuator is a square-wave signal of specified chopping frequency fᵣ,
the current I_{c} flowing in the load is a periodic signal whose phase is advanced relative to the voltage V_{c} and whose resonance frequency fₒ is such that the chopping frequency fᵣ lies between half and twice the resonance frequency, fₒ/2<fᵣ<2 f₀, in such a way that it activates zero-current closing of the switches in the driver switch, this hypo-continuous type of mode of activation of the switches being obtained from the transformation ratio of the transformer and of the resonance inductor determined as a function of the equivalent capacitance of the actuator.

According to another characteristic, the method for electronic activation of the driver device of at least one ultrasonic piezoelectric actuator from a control computer that is provided with a DC-to-AC step-up voltage converter supplied by a DC voltage source, the high-voltage output of which is connected to an oscillating circuit composed of the actuator and a resonance inductor, the said converter being composed of a circuit having at least one transformer with at least one primary winding connected to the voltage source by at least one drivable switch and a single secondary winding delivering an AC signal for excitation of the piezoelectric actuator, is characterized in that:
the voltage V_{c} at the terminals of the load composed of the transformer, resonance inductor and actuator is a square-wave signal of specified chopping frequency fᵣ,
the current Ic flowing in the load is a periodic signal whose phase is retarded relative to the voltage V_{c} and whose resonance frequency f₀ is such that the chopping frequency fᵣ is greater than half the resonance frequency, fᵣ>f₀/2, in such a way that it activates zero-voltage closing of the switches at the terminals of the driver switch, this hyper-continuous type of mode of activation of the switches being obtained from the transformation ratio of the transformer and of the resonance inductor determined as a function of the equivalent capacitance of the actuator.

Other characteristics and advantages of the invention will become apparent upon reading the description of several modes of electronic activation of a driver device of an ultrasonic piezoelectric actuator, illustrated by the following figures, which are:

FIG. 1: the electronic schematic of an embodiment of a sequential driver device of a group of four ultrasonic piezoelectric actuators;

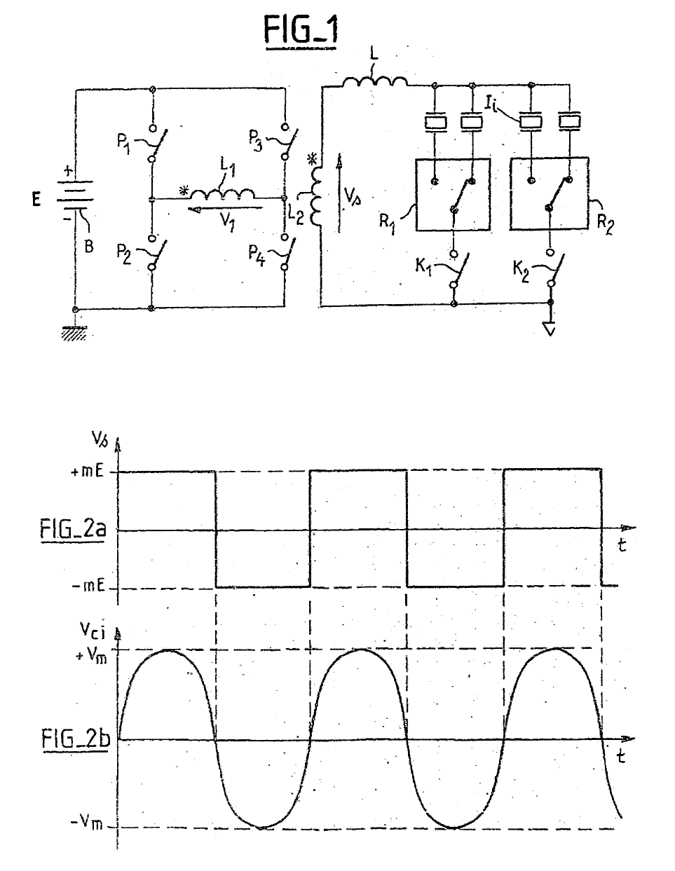

FIGS. 2a and 2b: the variations in time of the output voltage of the driver device and of the voltage at the terminals of a piezoelectric actuator;

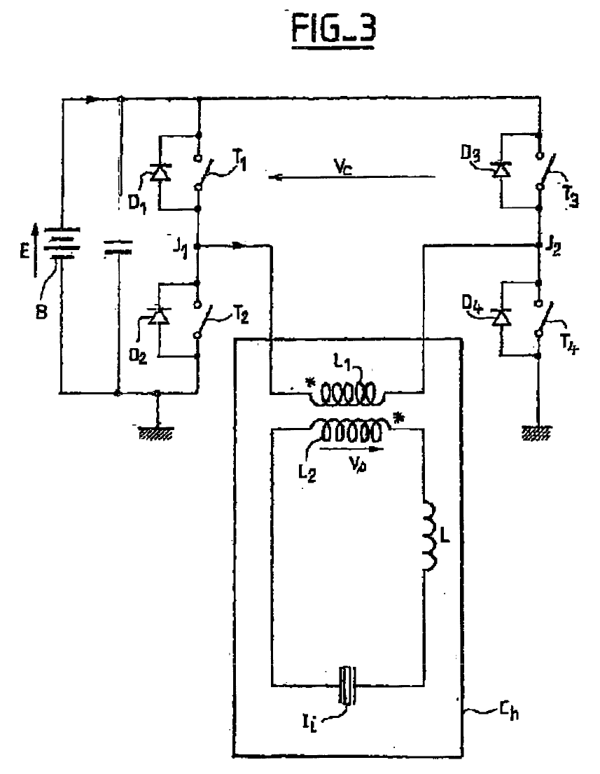

FIG. 3: the electronic schematic of an embodiment of a driver device in the bridge of a piezoelectric actuator;

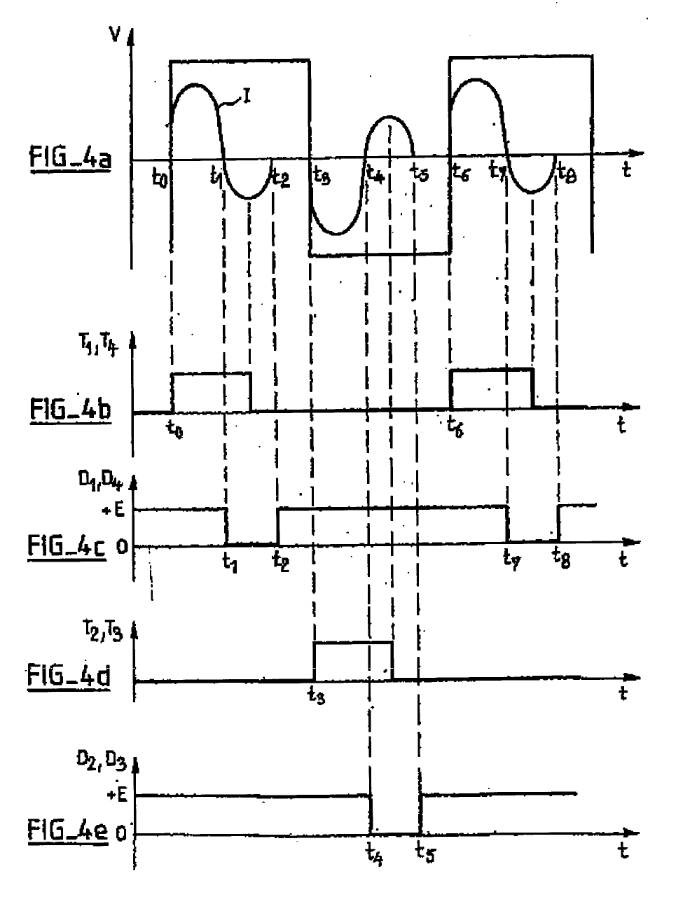

FIG. 4a: the waveform generated by the activation of the driver device in hypo-discontinuous mode according to the invention;

FIGS. 4b and 4d: the variations in time of the driving voltages at the terminals of the bridge transistors in hypo-discontinuous mode;

FIGS. 4c and 4e: representations of the voltages at the terminals of the bridge diodes in hypo-discontinuous mode;

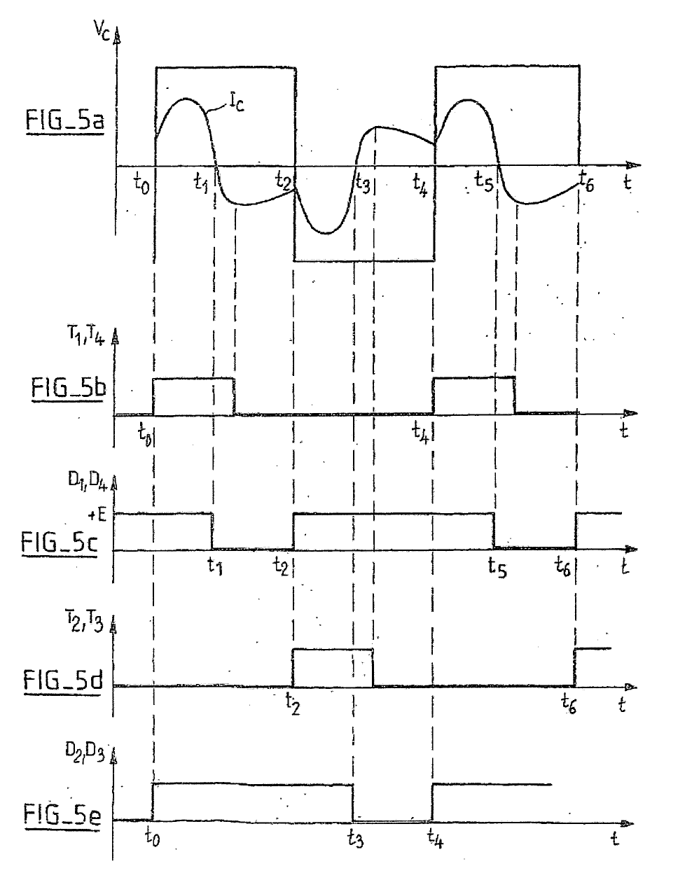

FIG. 5a: the waveform generated by the activation of the driver device in hypo-continuous mode according to the invention;

FIGS. 5b and 5d: the variations in time of the driving voltages at the terminals of the bridge transistors in hypo-continuous mode;

FIGS. 5c and 5e: representations of the voltages at the terminals of the bridge diodes in hypo-continuous mode;

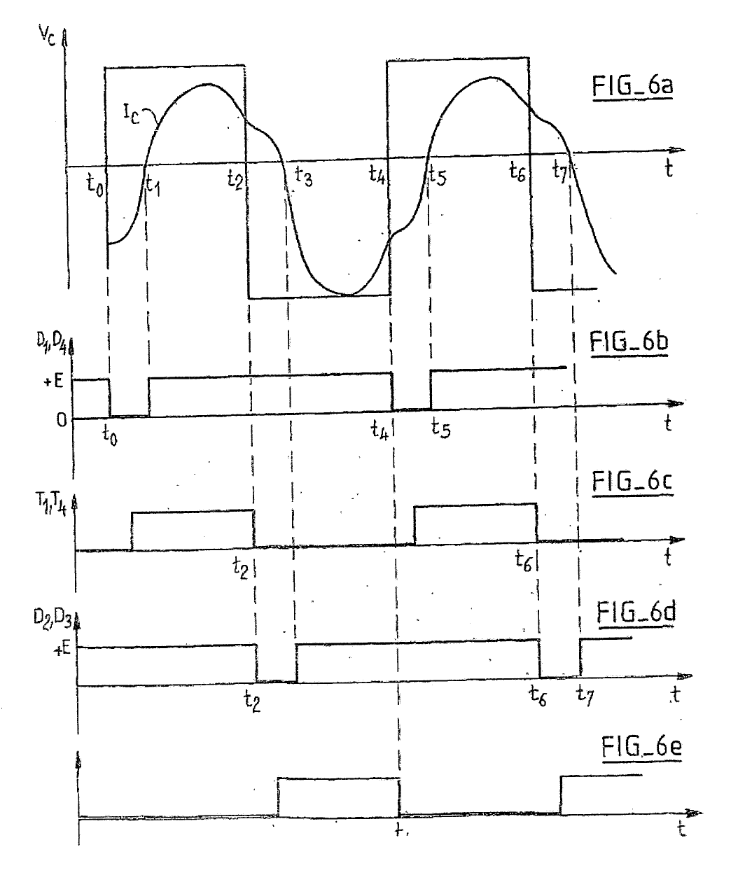

FIG. 6a: the waveform generated by the activation of the driver device in hyper-continuous mode according to the invention;

FIGS. 6b and 6d the variations in time of the driving voltages at the terminals of the bridge transistors in hyper-continuous mode;

FIGS. 6c and 6e: representations of the voltages at the terminals of the bridge diodes in hyper-continuous mode.

For these non-limitative examples of embodiments, elements bearing like references on the different figures perform like functions in order to achieve like results.

Since the invention comprises generating a sinusoidal signal of high voltage, greater than about one hundred volts, and of high frequency, greater than about ten kilohertz on the piezoelectric cell of each fuel injector of a vehicle from a DC voltage source, either the battery or the output of a power DC converter, it proposes the activation of a driver device according to different topologies that ensure excitation of the said piezoelectric ceramics via an inductor, in order to establish a resonant circuit. These topologies are described in the patent application cited hereinabove. These structures are valid for 1 to N injectors, where N is an integral number preferably equal to 4, 5, 6, 8, 10 or 12. As a non-limitative example, the number of driven injectors is 4 in the description hereinafter.

All the topologies described represent structures with at least one transformer having only a single winding in the secondary and one or two windings in the primary.

According to the schematic of FIG. 1, which represents a non-limitative structure with a single transformer, the driver device of one ultrasonic piezoelectric actuator lI among four, where i is an integral number varying from 1 to 4, is provided with a source B of DC voltage E—such as a battery or the output of a DC-to-DC converter—whose (−) terminal is connected to ground and whose (+) terminal is connected to a bridge circuit whose center load is the primary winding L₁ of a transformer. This transformer comprises two windings wound around the same core, as shown by the asterisks in the schematic, a primary winding L₁ and a secondary winding L₂, whose high-voltage output Vₛ is connected to an oscillating circuit composed of the piezoelectric ceramic stage Iᵢ and of a resonance inductor L. This resonance inductor is designed as a function of the operating frequency of the piezoelectric injector. It can also be placed in the primary of the transformer or even composed of the leakage inductor of the transformer.

This bridge circuit is established by two arms connected in parallel at the terminals of voltage source B and each composed of two alternately drivable series bridge switches P₁, P₂ and P₃, P₄ respectively, whose center points J_{1 and J}₂ respectively are connected to the two terminals of primary winding L₁.

In the case of an internal combustion engine of a motor vehicle that needs four injectors, the schematic represents four piezoelectric ceramics I₁, . . . , Iᵢ, . . . , I₄, which are connected in parallel and, in a first embodiment, are successively chosen by virtue of a drivable selection switch Kᵢ connected in series with each of them. The four injectors Iᵢ are connected on the one hand to resonance inductor L, intended to form an oscillating circuit with each injector in succession, and on the other hand are connected in pairs by relays R₁ and R₂ respectively, each of which is connected to one terminal of a selection switch K₁ and K₂ respectively, whose other terminal is connected to ground. The injection computer first activates all relays then simultaneously the selection and bridge switches to select the injector to be driven, which must be open during the intervals of activity in order to ensure that fuel is fed to the corresponding cylinder of the engine.

The operation of this driver circuit is as follows, depending on how the different switches are driven. In a first phase, the driving signal sent by the injection computer activates on the one hand closing of the selection switch Kᵢ connected to the chosen injector Iᵢ and on the other hand simultaneous closing of bridge switches P₁ and P₄, thus connecting terminal J₁ of primary winding L₁ to the (+) terminal of battery B and terminal J₂ thereof to the (−) terminal of the battery. During this time interval between instants T₀ and T₁, the voltage v₁ at the terminals of primary winding L₁ is equal to +E, such that the voltage Vₛ at the terminals of the secondary winding L₂ is positive and equal to +mE by the effect of the transformation ratio, thus permitting loading through resonance inductor L of the actuator Iᵢ selected by switch Kᵢ activated by the computer. Then, in a second phase, during the following time interval between times T_{1 and T}₂, the signal drives switches P₂ and P₄ to open position and simultaneously drives the two switches P₂ and P₃ to closed position, thus connecting terminal J₁ of primary winding L₁ to the (−) terminal of battery B and terminal J₂ thereof to the (+) terminal, voltage vᵢ at its negative terminals being equal to −E. Thus the voltage Vₛ at the terminals of secondary winding L₂ becomes negative and equal to −mE. These two phases are repeated a large number of times during the injection period, which lasts for between 100 μs and 8 ms. The periodic voltage Vₛ at the terminals of secondary winding L₂ as a function of time is represented graphically in FIG. 2a. Voltage V_{ci} at the terminals of injector Iᵢ is then a sinusoidal signal of the same period as voltage Vₛ at the terminals of secondary winding L₂, as shown in FIG. 2b, oscillating between a maximum value +Vₘ and a minimum value −Vₘ. The injection computer then successively drives the other injectors Iᵢ connected in parallel.

For excitation of injector I₁ between instants t₀ and t₁, the computer activates the relay R₁ into break position toward injector I₁ while relay R₂ is in break position, as well as the closing of switch K₁ and the opening of switch K₂, for the purpose of connecting actuator I₁ to resonance inductor L. Thus, between instants t₀ and t₁, the voltage Vₛ at the terminals of secondary winding L₂ is a periodic square-wave signal, oscillating between the extreme values +mE and −mE, and the voltage v_{c1} at the terminals of actuator I₁ is a sinusoidal signal oscillating between the extreme values +mGE and −mGE, where G is the resonance gain between resonance inductor L and the injector model, while the three other injectors do not receive any voltage. The closing duration T_{Ki} of each selection switch corresponds to the injection time, which can vary between 100 μs and 5 ms for a four-injector engine. The period T_{Pl} of the square-wave signal Vₛ at the terminals of the secondary winding of each transformer depends exclusively on the structure of the injectors, the resonance frequency F_{Pl} varying between 10 kHz and 1 MHz.

Since the toggling of a relay from break position to make position is longer than the opening or closing of a switch, the computer activates toggling of second relay R₂ into make position at instant t₂ for the purpose of being able to excite injector I₃ at the following instant t₃.

At instant t₃, relay R₂ is toggled to make position while relay R₂ is still toggled to make position toward injector I₃, and simultaneously switch K₂ is closed until instant t₄ while switch K, has been open since instant t₁, such that voltage Vₛ at the terminals of secondary winding L₃ causes resonance of the oscillating circuit composed of inductor L and injector I₃ to which it is then connected. Voltage signal V_{c3} at the terminals of injector I₃ is a sinusoid of maximum amplitude mGE between the following instants t₃ and t₄.

Between the following instants t₅ and t₆, switch K, is reclosed and switch K₂ is opened, but relay R₁ is toggled toward injector I₂ and therefore its driving signal is inverted relative to that existing between instants t₀ and t₁. Thus voltage signal V_{c2} at the terminals of injector I₂ is a sinusoid of maximum amplitude mGE between the following instants t₅ and t₆.

Between the following instants t₇ and t₈, switch K₂ is reclosed while switch K, is opened, and the two relays R_{1 and R}₂ are in break position, therefore relay R₂ is toggled toward injector I₄, and its driving signal is inverted relative to that existing between instants t₃ and t₄. Thus voltage signal V_{c4} at the terminals of injector I₄ is a sinusoid of maximum amplitude mGE between the following instants t₇ and t₈.

The invention relates to precisely the activation of bridge driver switches with respect to the load Cₕ connecting the center points of the two bridge arms, this load being composed of the transformer, resonance inductor and actuator, or in other words being a function of the current I_{c} flowing in this load and of the voltage V_{c} at its terminals. In the practical example of FIG. 3, the bridge switches Pᵢ are each composed of a transistor Tᵢ and of a diode Dᵢ connected in anti-parallel. For the periodic voltage V₅ at the terminals of the secondary winding of the transformer to permit excitation of piezoelectric actuator Iᵢ, the voltage V_{c} at the terminals of the load must be of square-wave form and of specified chopping frequency fᵣ.

According to a first characteristic of the invention, since the voltage V_{c} at the terminals of the load composed of a transformer, resonance inductor and actuator is a square-wave signal of specified chopping frequency fᵣ, the current I_{c} flowing in the load is a periodic signal of resonance frequency fₒ such that the chopping frequency fᵣ is at least two times smaller than it, fᵣ<2 fₒ, in such a way that, upon closing of the switches, the current is zero in the circuit. This type of hypo-discontinuous mode of activation of the driver switches is obtained from the values of the transformation ratio of the transformer and of the resonance inductor determined as a function of the value of the equivalent capacitance of the actuator. It makes it possible to limit the switching losses of the switches during their closing and to limit the effects of electromagnetic compatibility by current breaking.

The DC-to-AC step-up voltage converter is dimensioned such that the chopping frequency fᵣ needed to activate the piezoelectric injector is lower than twice the resonance frequency of the load.

FIG. 4a represents the waveform generated by the bridge of the driver device in hypo-discontinuous mode according to the invention.

To drive the given actuator I, the control computer activates on the one hand closing of selection means connected to the said actuator and on the other hand simultaneously, in a first phase, closing of a first pair of bridge switches composed of a first switch T₁ of the first arm and of a second switch T₄ of a second arm and the opening of the second pair formed by the two other switches T₂ and T₃ of the said arms and, in a second phase, the switching of the said four switches into an inverse position in such a way as to obtain a periodic voltage at the terminals of the secondary winding of the transformer, these two phases being repeated a specified number of times during the period of operation of the actuator to generate a high-voltage, high-frequency signal on the piezoelectric actuator from the DC voltage source.

Thus the sequencing of activation of the four switches of the driver device is as follows during two consecutive phases, the first of which takes place between instants t₀ and t₃ and the second takes place between instants t₃ and t₆.

At instant to of starting of the first phase, transistors T_{1 and T}₄ are driven to closed position when current I_{c} is zero in diodes D₁ and D₄.

Between instants t₀ and t₁, these transistors T₁ and T₄ are closed to allow current I_{c} to flow, while diodes D₁ and D₄ are nonconducting, the voltage at their terminals being equal to +E.

At instant t₁, current I_{c} is inverted, the two diodes become conducting, the voltage at their terminals drops to zero and the two transistors T₁ and T₄ are driven to open position between this instant t₁ and instant t₂, at which the diodes are no longer conducting and the current drops to zero.

At instant t₃ of starting of the second phase, transistors T₂ and T₃ are driven to closed position when current I_{c} is zero in diodes D₂ and D₃.

Between instants t₃ and 4, these transistors T₂ and T₃ are closed to allow current I_{c} to flow, while diodes D₂ and D₃ are nonconducting.

At instant 4, current I_{c} is inverted, the two diodes become conducting and the two transistors T₂ and T₃ are driven to open position between this instant t₄ and instant t₅, at which the diodes are no longer conducting and the current again drops to zero.

FIGS. 4b and 4d represent the variations in time of the driving voltages at the terminals of the bridge transistors, and FIGS. 4c and 4e represent the voltages at the terminals of the diodes connected in parallel with these bridge transistors, or in other words their conducting or nonconducting states.

According to a second characteristic of the invention, since the voltage V_{c} at the terminals of the load composed of the transformer, resonance inductor and actuator is a square-wave signal of specified chopping frequency fᵣ, the current I_{c} flowing in the load is a periodic signal, whose phase is advanced relative to voltage V_{c} and whose resonance frequency fₒ is such that the chopping frequency fᵣ is between half and twice the resonance frequency fₒ, fₒ/2<fᵣ<2 fₒ, in such a way that it activates zero current switching (ZCS) of the switches in the driver switch. This type of hypo-continuous mode of activation of the driver switches is obtained from the values of the transformation ratio of the transformer and of the resonance inductor determined as a function of the value of the equivalent capacitance of the actuator. Since this mode of activation of the driver switches is of the hypo-continuous type, it makes it possible to limit the switching losses of the switches during their opening and to limit the effects of electromagnetic compatibility by current breaking.

The DC-to-AC step-up voltage converter is dimensioned such that the chopping frequency fᵣ needed to activate the piezoelectric injector satisfies the conditions indicated in the foregoing with respect to the resonance frequency fₒ.

FIG. 5a represents the waveform generated by the bridge of the driver device in hypo-continuous mode according to the invention.

The sequencing of activation of the four switches T₁ to T₄ of the driver device is as follows during two consecutive phases, the first of which takes place between instants t₀ and t₂ and the second takes place between instants t₂ and t₄.

At instant t0, transistors T₁ and T₄ are driven to closed position when current I_{c} is zero in diodes D₁ and D₄ and when the other diodes D₂ and D₃ are conducting.

Between instants t₀ and t₁, these transistors T₁ and T₄ are closed to allow current I_{c} to flow, while the four diodes D₁ to D₄ are nonconducting.

At instant t₁, current I_{c} is inverted, the two diodes D₁ and D₄ become conducting and the two transistors T_{1 and T}₄ are driven to open position between this instant t₁ and instant t₂, at which there is no current in these two transistors.

At this same instant t₂, transistors T₂ and T₃ are driven to closed position while diodes D₁ and D₄ are still conducting. At this instant of closing, diodes D₁ and D₄ are naturally nonconducting and current I_{c} flows in the same sense.

Between instants t₃ and 4, current I_{c} is inverted and diodes D₂ and D₃ become conducting and these transistors T₂ and T₃ are driven to open position while there is no longer any current Ic present in these transistors.

At instant 4, the two transistors T_{1 and T}₄ are driven to closed position, the two diodes D₂ and D₃ become nonconducting and activation recommences according to the same sequencing as between instants t₀ and 4.

FIGS. 5b and 5d represent the variations in time, in hypo-continuous mode, of the driving voltages at the terminals of the bridge transistors, and FIGS. 5c and 5e represent the voltages at the terminals of the diodes connected in parallel with these bridge transistors, or in other words their conducting or nonconducting states.

According to a third characteristic of the invention, since the voltage V_{c} at the terminals of the load composed of the transformer, resonance inductor and actuator is a square-wave signal of specified chopping frequency fr, the current Ic flowing in the load is a periodic signal, whose phase is retarded relative to voltage V_{c} and whose resonance frequency f₀ is such that the chopping frequency fᵣ is greater than half of the resonance frequency fₒ, fᵣ>f₀/2, in such a way that it activates zero voltage switching at the terminals of the driver switch. This type of hyper-continuous mode of activation of the driver switches is obtained from the values of the transformation ratio of the transformer and of the resonance inductor determined as a function of the value of the equivalent capacitance of the actuator. This hyper-continuous mode of activation of the driver switches makes it possible to limit the switching losses of the switches during their opening and to limit the effects of electromagnetic compatibility by voltage switching. This mode of activation is of the zero voltage switching (ZVS) type for driving the switches to closed position.

The DC-to-AC step-up voltage converter is dimensioned such that the chopping frequency fᵣ needed to activate the piezoelectric injector satisfies the conditions indicated in the foregoing with respect to the resonance frequency fₒ.

FIG. 6a represents the waveform generated by the bridge of the driver device in hyper-continuous mode according to the invention.

The sequencing of activation of the four switches of the driver device is as follows during two consecutive phases, the first of which takes place between instants to and t₂ and the second takes place between instants t₂ and t₄.

Between instants t₀ and t₁, transistors T_{1 and T}₄ are driven to closed position while the two diodes D₁ and D₂ are conducting, and therefore while no voltage is present at the terminals of these transistors. The other diodes D₂ and D₃ are nonconducting and the two transistors T₂ and T₃ are open.

At instant t₁, diodes D₁ and D₄ are nonconducting.

Between instants t₁ and t₂, transistors T_{1 and T}₄ are still closed, allowing current I_{c} to flow.

At instant t₂, the transistors T₁ and T₄ are driven to open position, diodes D₂ and D₃ become conducting and voltage is no longer present at the terminals of transistors T₂ and T₃. Diodes D_{1 and D}₄ are nonconducting.

Between instants t₂ and t₃, transistors T₂ and T₃ are driven to closed position, after which they are driven to open position at instant t₄.

FIGS. 6b and 6d represent the variations in time, in hyper-continuous mode, of the driving voltages at the terminals of the bridge transistors, and FIGS. 6c and 6e represent the voltages at the terminals of the diodes connected in parallel with these bridge transistors, or in other words their conducting or nonconducting states.

According to another characteristic of the invention, the activation method combines, in time, the three modes of activation of the switches, or in other words the hypo-discontinuous, hypo-continuous and hyper-continuous types, as a function of the battery voltage E, which can vary, and of the peak setpoint voltage of the activation signal of the piezoelectric actuators.

The selection switches of the actuators and of the primary windings of the transformers are bidirectionally drivable in current, and for this purpose can be composed of two semiconductors connected in series or in parallel. As an example, they can be two transistors of the MOSFET type connected in series or of the IGBT type with antiparallel diode.

The actuator selection relays R are of monostable electromechanical type and have a break contact and a make contact.

As for bridge switches, if they are placed directly on the output side of the battery, they are preferably of the N-channel MOSFET type because of their low voltage drops. In the case in which they are placed on the output side of a DC-to-DC converter, these switches may be of the MOSFET or IGBT type.

As regards the transformer selection switches, they are preferably of the P-channel MOSFET type because of their low voltage drops.

1. A method for electronic activation of a driver device of at least one ultrasonic piezoelectric actuator from a control computer that is provided with a DC-to-AC step-up voltage converter supplied by a DC voltage source (B), the high-voltage output of which is connected to an oscillating circuit composed of the actuator (Iᵢ) and a resonance inductor (L), the said converter being composed of a circuit having at least one transformer with at least one primary winding connected to the voltage source by at least one drivable switch and a single secondary winding delivering an AC signal for excitation of the piezoelectric actuator, and such that the voltage (V_{c}) at the terminals of the load composed of the transformer, resonance inductor and actuator is a square-wave signal of specified chopping frequency (fᵣ), characterized in that the current (I_{c}) flowing in the load is a periodic signal of resonance frequency (fₒ) such that the chopping frequency (fᵣ) is smaller than twice the resonance frequency, such that it activates zero-current closing of the switches in the circuit, this hypo-discontinuous type of mode of activation of the switches being obtained from the transformation ratio of the transformer and of the resonance inductor determined as a function of the equivalent capacitance of the actuator.

2. A method for electronic activation of the driver device of at least one ultrasonic piezoelectric actuator from a control computer that is provided with a DC-to-AC step-up voltage converter supplied by a DC voltage source, the high-voltage output of which is connected to an oscillating circuit composed of the actuator and a resonance inductor, the said converter being composed of a circuit having at least one transformer with at least one primary winding connected to the voltage source by at least one drivable switch and a single secondary winding delivering an AC signal for excitation of the piezoelectric actuator, which method is characterized in that:
the voltage (V_{c}) at the terminals of the load composed of the transformer, resonance inductor and actuator is a square-wave signal of specified chopping frequency (fᵣ),
the current (I_{c}) flowing in the load is a periodic signal whose phase is advanced relative to the voltage (V_{c}) and whose resonance frequency (fₒ) is such that the chopping frequency (fᵣ) lies between half and twice the resonance frequency, (fₒ/2<fr<2f₀), in such a way that it activates zero-current closing of the switches in the driver switch, this hypo-continuous type of mode of activation of the switches being obtained from the transformation ratio of the transformer and of the resonance inductor determined as a function of the equivalent capacitance of the actuator.

3. A method for electronic activation of the driver device of at least one ultrasonic piezoelectric actuator from a control computer that is provided with a DC-to-AC step-up voltage converter supplied by a DC voltage source, the high-voltage output of which is connected to an oscillating circuit composed of the actuator and a resonance inductor, the said converter being composed of a circuit having at least one transformer with at least one primary winding connected to the voltage source by at least one drivable switch and a single secondary winding delivering an AC signal for excitation of the piezoelectric actuator, which method is characterized in that:
the voltage (V_{c}) at the terminals of the load composed of the transformer, resonance inductor and actuator is a square-wave signal of specified chopping frequency (fᵣ),
the current (I_{c}) flowing in the load is a periodic signal whose phase is retarded relative to the voltage (V_{c}) and whose resonance frequency (fₒ) is such that the chopping frequency (fᵣ) is greater than half the resonance frequency, (fᵣ>f₀/2), in such a way that it activates zero-voltage closing of the switches at the terminals of the driver switch, this hyper-continuous type of mode of activation of the switches being obtained from the transformation ratio of the transformer and of the resonance inductor determined as a function of the equivalent capacitance of the actuator.

4. A method for electronic activation of the driver device of at least one ultrasonic piezoelectric actuator, provided with a converter composed of a bridge circuit containing at least one transformer having at least one primary winding, established from a first arm composed of two alternately drivable bridge switches (T₁, T₂) in series and of at least one second arm in parallel with the first arm and also composed of two alternately drivable bridge switches (T₂, T₃) in series, the center point of the second arm being connected to the center point of the first arm by a load composed of the transformer, resonance inductor (L) and piezoelectric actuator according to claim 1, characterized in that the sequencing of activation of the four switches of the converter is as follows: during a first phase:
at the instant (t₀), a first transistor (T₁) of the first arm and a second switch (T₂) of the second arm constituting a first pair are driven to closed position when the current (I_{c}) is zero in the diodes (D₁ and D₄) in antiparallel;
between the instants (t₀ and t₁), the transistors (T₁ and T₄) of the first pair are closed to allow a current (I_{c}) to flow, while the diodes (D₁ and D₄) are nonconducting and the second transistor (T₂) of the first arm and the first transistor (T₃) of the second arm constituting a second pair are open;
at the instant (t₁), the current (I_{c}) is inverted, the two diodes (D₁ and D₄) become conducting and the two transistors (T₁ and T₄) of the first pair are driven to open position between this instant (t₁) and the instant (t₂), at which the diodes (D₁ and D₄) are no longer conducting, the current dropping to zero; during a second phase:
at the instant (t₃), the transistors (T₂ and T₃) of the second pair are driven to closed position when the current (I_{c}) is zero in the diodes (D₂ and D₃) in antiparallel;
between the instants (t₃ and t₄), these transistors (T₂ and T₃) are closed to allow the current (I_{c}) to flow, while the diodes (D₂ and D₃) are nonconducting and the transistors (T₁ and T₄) of the first pair are open;
at the instant (t₄), the current (I_{c}) is inverted, the two diodes (D₂ and D₃) become conducting and the two transistors (T₂ and T₃) are driven to open position between this instant (t₄) and the instant (t₅), at which the diodes are no longer conducting, the current again dropping to zero,
these two phases being repeated a specified number of times during the period of operation of the actuator to generate a high-voltage, high-frequency signal on the piezoelectric actuator from the DC voltage source.

5. A method for electronic activation of the driver device of at least one ultrasonic piezoelectric actuator, provided with a converter composed of a bridge circuit containing at least one transformer having at least one primary winding, established from a first arm composed of two alternately drivable bridge switches (T₁, T₂) in series and of at least one second arm in parallel with the first arm and also composed of two alternately drivable bridge switches (T₂, T₃) in series, the center point of the second arm being connected to the center point of the first arm by a load composed of the transformer, resonance inductor (L) and piezoelectric actuator according to claim 2, characterized in that the sequencing of activation of the four switches of the converter is as follows: during a first phase:
at the instant (t₀), a first transistor (T₁) of the first arm and a second switch (T₄) of the second arm constituting a first pair are driven to closed position when the current (I_{c}) is zero in the diodes (D₁ and D₄) in antiparallel and while the other diodes (D₂ and D₃) in antiparallel of the second transistor (T₂) of the first arm and of the first transistor (T₃) of the second arm are conducting;
between the instants (t₀ and t₁), the transistors (T₁ and T₄) of the first pair are closed to allow the current (I_{c}) to flow, while the four diodes (D₁ to D₄) are nonconducting;
at the instant (t₁), the current (I_{c}) is inverted, the two diodes (D₁ and D₄) become conducting and the two transistors (T₁ and T₄) are driven to open position between this instant (t₁) and the instant (t₂), at which no current is present in these two transistors;
at this same instant (t₂), the transistors (T₂ and T₃) of the second pair are driven to closed position while the diodes (D₁ and D₄) are still conducting. At this instant of closing, the diodes (D₁ and D₄) are naturally nonconducting and the current I_{c} flows in the same sense;
between the instants (t₃ and t₄), the current (I_{c}) is inverted and the diodes (D₂ and D₃) become conducting and these transistors (T₂ and T₃) are driven to open position while there is no longer any current (I_{c}) present in these transistors;
at the instant (t₄), the two transistors (T₁ and T₄) are driven to closed position, the two diodes (D₂ and D₃) become nonconducting and activation recommences according to the same sequencing as between the instants (t₀ and t₄).

6. A method for electronic activation of the driver device of at least one ultrasonic piezoelectric actuator, provided with a converter composed of a bridge circuit containing at least one transformer having at least one primary winding, established from a first arm composed of two alternately drivable bridge switches (T₁, T₂) in series and of at least one second arm in parallel with the first arm and also composed of two alternately drivable bridge switches (T₂, T₃) in series, the center point of the second arm being connected to the center point of the first arm by a load composed of the transformer, resonance inductor (L) and piezoelectric actuator according to claim 3, characterized in that the sequencing of activation of the four switches of the converter is as follows:
during a first phase:
between the instants (t₀ and t₁), a first transistor (T₁) of the first arm and a second switch (T₄) of the second arm constituting a first pair are driven to closed position when the two diodes (D₁ and D₂) in antiparallel and the other diodes (D₂ and D₃) in antiparallel of the second transistor (T₂) of the first arm and of the first transistor (T₃) of the second arm are nonconducting and the two transistors (T₂ and T₃) are open;
at the instant (t1), the diodes (D_{1 and D}₄) of the first pair of transistors are nonconducting;
between the instants (t₁ and t₂), the two transistors (T₁ and T₄) of the first pair are still closed, allowing the current (I_{c}) to flow;
at the instant (t₂), the transistors (T₁ and T₄) of the first pair are driven to open position, the diodes (D₂ and D₃) in antiparallel of the second pair of transistors become conducting and voltage is no longer present at the terminals of the transistors (T₂ and T₃), the diodes (D₁ and D₄) being nonconducting;
between the instants (t₂ and t₃), the transistors (T₂ and T₃) of the second pair are driven to closed position, after which they are driven to open position at the instant (t₄).

7. A method for electronic activation of a driver device of at least one ultrasonic piezoelectric actuator according to one of claims 1 to 6, characterized in that it combines, in time, the three modes of activation of the switches, or in other words the hypo-discontinuous, hypo-continuous and hyper-continuous types, as a function of the battery voltage E, which can vary, and of the peak setpoint voltage of the activation signal of the piezoelectric actuators.
